(19) United States
(12) Patent Application Publication
(10) Pub. No.: US 2024/0073503 A1
(43) Pub. Date: Feb. 29, 2024

(54) CAMERA MODULE

(71) Applicant: Samsung Electro-Mechanics Co., Ltd., Suwon-si (KR)

(72) Inventor: Jihae LEE, Suwon-si (KR)

(73) Assignee: Samsung Electro-Mechanics Co., Ltd., Suwon-si (KR)

(21) Appl. No.: 18/326,385

(22) Filed: May 31, 2023

(30) Foreign Application Priority Data
Aug. 26, 2022 (KR) 10-2022-0107507

(51) Int. Cl. H04N 23/54; H04N 23/51

(52) U.S. Cl. CPC H04N 23/54; H04N 23/51

(57) ABSTRACT

A camera module includes a lens barrel, a housing configured to accommodate the lens barrel, an image sensor disposed below the lens barrel and mounted on a substrate, along an optical axis direction of the lens barrel, and a sub-housing, disposed between the lens barrel and the substrate, including an opening in which the image sensor is accommodated and a protrusion having a convexly curved upper surface shape configured to extend toward the lens barrel.

### CROSS-REFERENCE TO RELATED APPLICATION

This application claims the benefit under 35 USC 119(a) of Korean Patent Application No. 10-2022-0107507 filed in the Korean Intellectual Property Office on Aug. 26, 2022, the entire disclosure of which is incorporated herein by reference for all purposes.

### BACKGROUND

### 1. Field

The present disclosure relates to a camera module.

### 2. Description of the Related Art

With the remarkable development of information and communication technology and semiconductor technology, the supply and use of electronic devices are rapidly increasing. These electronic devices tend to provide various functions by convergence rather than staying in their typical unique domains.

Cameras are adopted in portable electronic devices such as smartphones, tablet PCs, and laptop computers, and the cameras may include auto focus (AF) functions, image stabilizer functions, and zoom functions.

As electronic devices including camera modules become thinner, the size of the camera module also decreases; however, there may not be enough space for disposing additional structures to prevent a flare phenomenon that may occur when light that has passed through a lens is diffusely reflected after re-entering toward the lens.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a camera module includes a lens barrel, a housing configured to accommodate the lens barrel, an image sensor disposed below the lens barrel and mounted on a substrate, along an optical axis direction of the lens barrel, and a sub-housing, disposed between the lens barrel and the substrate, including an opening in which the image sensor is accommodated and a protrusion having a convexly curved upper surface shape configured to extend toward the lens barrel.

The sub-housing may further include a bottom part disposed at an outer portion of the opening to surround the opening, and the protrusion may convexly protrude along a direction extending from a central portion of the image sensor toward the housing.

The sub-housing may further include a mounting part disposed between the protrusion and the opening, and the camera module may further include a filter part accommodated in the mounting part.

A thickness of the mounting part may be greater than a thickness of the bottom part, and may be smaller than a thickness of the protrusion.

The sub-housing may have a quadrangular planar shape.

The opening may have a quadrangular planar shape.

The mounting part may have a quadrangular planar shape.

The protrusion may include a plurality of pattern parts disposed along an edge of the mounting part and an outermost edge of the sub-housing, respectively, and having the convexly curved upper surface shape.

The protrusion may further include a plurality of corner pattern parts disposed between a plurality of first points at which outer edges of the sub-housing, extending in different directions, cross each other and a plurality of second points at which outer edges of the mounting part, extending in different directions, cross each other.

Upper surfaces of the plurality of corner pattern parts may have convexly curved shape shapes.

The plurality of corner pattern parts may have a shape of the surface convexly protruding along a direction extending from a central portion of the image sensor toward the housing.

The sub-housing may further include a mounting part disposed between the protrusion and the opening, and the camera module may further include a filter part accommodated in the mounting part.

Each of the sub-housing, the opening, and the mounting part may have a quadrangular planar shape.

The protrusion may include a plurality of pattern parts disposed along an edge of the mounting part and an outermost edge of the sub-housing, respectively, and having the convexly curved upper surface shape.

The protrusion may further include a plurality of corner pattern parts disposed between a plurality of first points at which outer edges of the sub-housing, extending in different directions, cross each other and a plurality of second points at which outer edges of the mounting part, extending in different directions, cross each other.

Upper surfaces of the plurality of corner pattern parts may have convexly curved shapes.

The corner pattern part may have a shape of the surface convexly protruding along a direction extending from a central portion of the image sensor toward the housing.

The protrusion may include a plurality of pattern parts respectively disposed along an outermost edge of the sub-housing and having the convexly curved upper surface shape, and a plurality of corner pattern parts, disposed at a plurality of first points at which outer edges of the sub-housing extending in different directions, cross each other.

Upper surfaces of the plurality of corner pattern parts may have convexly curved shapes.

The corner pattern part may have a shape of the surface convexly protruding along a direction extending from a central portion of the image sensor toward the housing.

Other features and aspects will be apparent from the following detailed description, the drawings, and the claims.

### BRIEF DESCRIPTION OF THE DRAWINGS

FIG. 1 illustrates a schematic cross-sectional view of a camera module according to one or more embodiments.

FIG. 2 illustrates a top plan view of a portion of a camera module according to one or more embodiments.

FIG. 3 illustrates a perspective view of a portion of a camera module according to one or more embodiments.

FIG. 4 schematically illustrates a light path of a camera module according to one or more embodiments.

FIG. 5 schematically illustrates a light path of a camera module according to a prior art.

FIG. 6 illustrates a top plan view of a portion of a camera module according to another one or more embodiments.

Throughout the drawings and the detailed description, the same reference numerals refer to the same or like elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, various embodiments and variations will be described in detail with reference to the drawings.

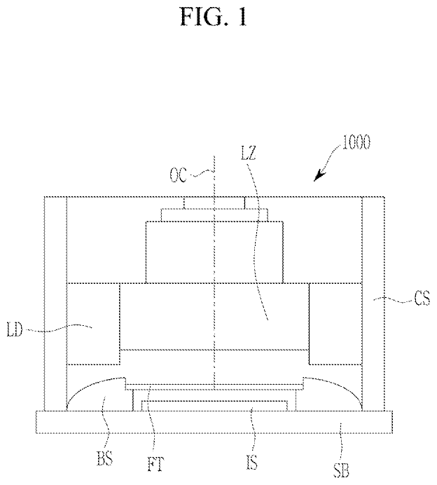

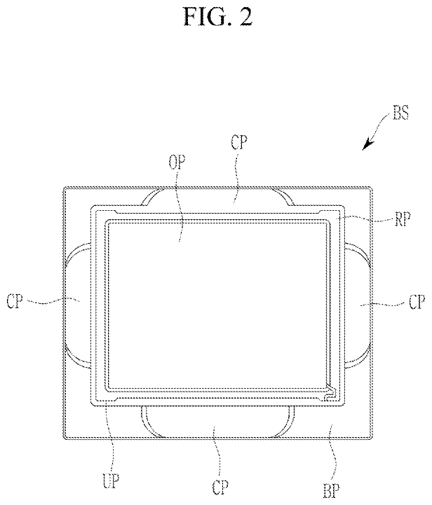

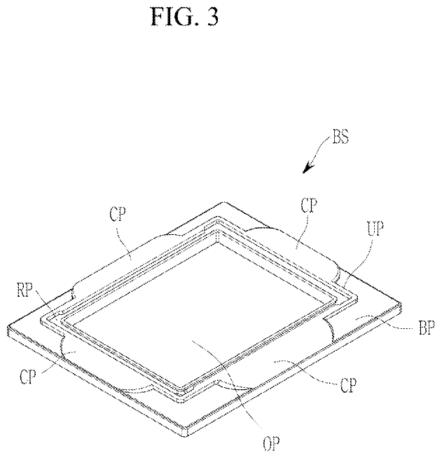

Referring to FIG. 1 to FIG. 3, a camera module 1000 will be described according to one or more embodiments. FIG. 1 illustrates a schematic cross-sectional view of a camera module according to one or more embodiments, FIG. 2 illustrates a top plan view of a portion of a camera module according to one or more embodiments, and FIG. 3 illustrates a perspective view of a portion of a camera module according to one or more embodiments.

First, referring to FIG. 1, the camera module 1000, according to the embodiment, may include a housing CS, a lens barrel LZ, a lens driver LD, a sub-housing BS, an image sensor IS, and a filter part FT.

The housing CS may accommodate the lens barrel LZ and the lens driver LD. The housing CS may have a polyhedral shape having a substantially quadrangular cross-section and a predetermined height. However, the shape of the housing CS is not limited to the polyhedral shape having a quadrangular cross-section.

The lens barrel LZ may include a plurality of lenses that are disposed along an optical axis direction OC.

The lens barrel LZ may move along the optical axis direction OC while being accommodated in the housing CS by the driving force of the lens driver LD.

The lens driver LD may provide the driving force desired to drive the lens barrel LZ. For example, the lens driver LD may drive the lens barrel LZ in the optical axis direction OC through electromagnetic force. As the lens barrel LZ moves in the optical axis direction OC, the lens barrel LZ may be focused.

A substrate SB may be electrically connected to the lens driver LD. The substrate SB may be an FPCB.

The image sensor IS may be mounted on the substrate SB. Along the optical axis direction OC, the image sensor IS may be disposed below the lens barrel LZ.

The sub-housing BS and the filter part FT mounted on the sub-housing BS may be disposed between the substrate SB on which the image sensor IS is mounted and the lens barrel LZ.

The image sensor IS may be disposed inside the sub-housing BS.

As such, the housing CS and the sub-housing BS may define an inner space in which the lens barrel LZ, the lens driver LD, and the image sensor IS are accommodated.

Hereinafter, the sub-housing BS of the camera module 1000, according to the present embodiment, will be described in more detail with reference to FIG. 2 and FIG. 3 together with FIG. 1.

The sub-housing BS may have a quadrangular planar shape, the sub-housing BS may have an opening OP formed in a center thereof, and the image sensor IS may be disposed within the opening OP of the sub-housing BS. The opening OP of the sub-housing BS may also have a quadrangular planar shape.

The sub-housing BS may include: a mounting part RP surrounding the opening OP in which the image sensor IS is accommodated, and on which the filter part FT is mounted; a protrusion UP surrounding the mounting part RP and having a higher height than the mounting part RP; and a bottom part BP that is connected to the protrusion UP to extend up to an outer edge of the sub-housing BS and has a lower height than the protrusion.

The thickness of the mounting part RP may be greater than the thickness of the sub-housing BS, and may be smaller than the thickness of the protrusion UP. The mounting part RP may have a quadrangular planar shape, but is not limited thereto.

The protrusion UP may include a plurality of pattern parts CP that are disposed along an outer edge of the sub-housing BS and an outer edge of the mounting part RP.

The plurality of pattern parts CP may have the highest height at a portion adjacent to the outer edge of the mounting part RP, and may gradually decrease in height toward four outermost edges of the sub-housing BS. Upper surfaces of the plurality of pattern parts CP may have a convexly curved shape in a direction from a center portion of the image sensor IS toward the housing CS.

As described above, the sub-housing BS may have a quadrangular planar shape, and the mounting part RP may also have a quadrangular planar shape. The plurality of pattern parts CP may include four pattern parts CP, each disposed along four edges of the mounting part RP and four outermost edges of the sub-housing BS.

In a direction parallel to the four edges of the sub-housing BS, widths of the plurality of pattern parts CP are greatest in a portion adjacent to the outer edge of the mounting part RP, and may gradually decrease toward the four outermost edges of the sub-housing BS.

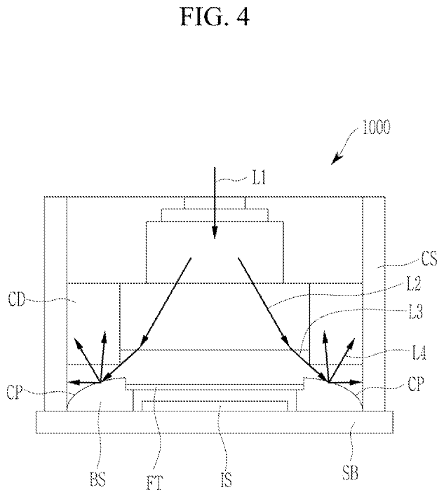

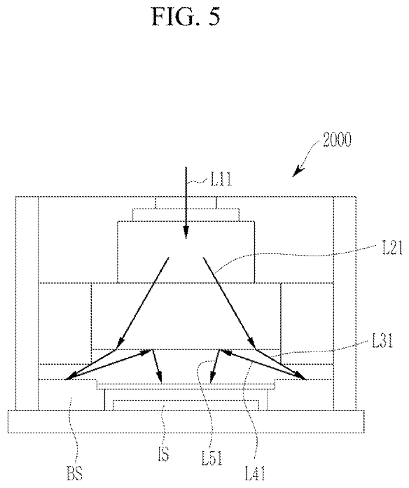

Hereinafter, a light path of a camera module according to one or more embodiments will be described with reference to FIG. 4 and FIG. 5 together with FIG. 1 to FIG. 3. FIG. 4 schematically illustrates a light path of a camera module according to one or more embodiments, and FIG. 5 schematically illustrates a light path of a camera module according to prior art.

Referring to FIG. 4, the first light L1 incident on the lens barrel LZ may mostly be incident on the image sensor IS through the filter part FT while passing through the lens barrel LZ, and second light L2 that is some of the first light L1 may be refracted toward the sub-housing BS disposed at an outer portion of the image sensor IS while passing through the lens barrel LZ.

After passing through the lens barrel LZ, the second light L2 refracted toward the sub-housing BS may be incident on the sub-housing BS surrounding an edge of the image sensor IS. Third light L3 incident on the sub-housing BS may be reflected on the plurality of pattern parts CP. Fourth light L4 reflected on the plurality of pattern parts CP may be emitted in a direction toward the outer portion of the sub-housing BS, not in a direction toward the lens barrel LZ.

As described above, the plurality of pattern parts CP may have the highest height in a portion adjacent to the outer edge of the mounting part RP, and may gradually decrease in height toward the four outermost edges of the sub-housing BS, and the upper surfaces of the plurality of pattern parts CP may have a convexly curved shape in a direction from the central portion of the image sensor IS toward the side case CS, so that light incident toward the sub-housing BS may be reflected in various directions from the convexly curved surfaces of the plurality of pattern parts CP toward the outer portion of the sub-housing BS.

Generally, as shown in FIG. 5, according to a camera module according to the prior art, the sub-housing BS does not include the plurality of pattern parts CP. Accordingly, second light L21 that is some of first light L11 incident on the lens barrel LZ may be refracted toward the sub-housing BS disposed at the outer portion of the image sensor IS while passing through the lens barrel LZ; the second light L21 refracted toward the sub-housing BS may be incident on the sub-housing BS after passing through the lens barrel LZ; and third light L31 incident on the sub-housing BS may be reflected from the upper surface of the sub-housing BS. Fourth light L41 that is at least some of the light reflected on the upper surface of the sub-housing BS may be reflected in a direction toward the lens barrel LZ; the fourth light L41 may be reflected back on the surface of the lens barrel LZ; and fifth light L51 reflected back on the surface of the lens barrel LZ may be incident back to the image sensor IS.

As such, some of the light incident on the lens barrel LZ may be incident on the sub-housing BS, may be additionally incident on the lens barrel LZ from the sub-housing BS, and then may be reflected from the lens barrel LZ to be additionally incident toward the image sensor IS, and the flare phenomenon may occur in the camera module by the fifth light L51 additionally incident toward the image sensor IS.

In addition, as the size of the camera module decreases, there is a restriction on a space for disposing an additional structure for preventing the flare phenomenon, and the thickness of the lens barrel LZ may also be reduced, thereby making it difficult to prevent the flare phenomenon.

However, according to the camera module according to the present embodiment, the sub-housing BS disposed at the outer portion of the image sensor IS includes the plurality of pattern parts CP, and the upper surfaces of the plurality of pattern parts CP may have a convexly curved shape in a direction from the central portion of the image sensor IS toward the housing CS. Accordingly, the light incident on the sub-housing BS may be reflected in a direction from the convexly curved surface of the plurality of pattern parts CP toward the outer portion of the sub-housing BS, and accordingly, the light that may be reflected from the sub-housing BS and that may be incident toward the lens barrel LZ is relatively reduced, so that the light reflected from the surface of the lens barrel LZ and unnecessarily incident toward the image sensor IS may be prevented.

Accordingly, without including an additional structure between the lens barrel LZ and the image sensor IS, the flare phenomenon may be prevented by reducing the light that may be reflected from the sub-housing BS and incident toward the lens barrel LZ.

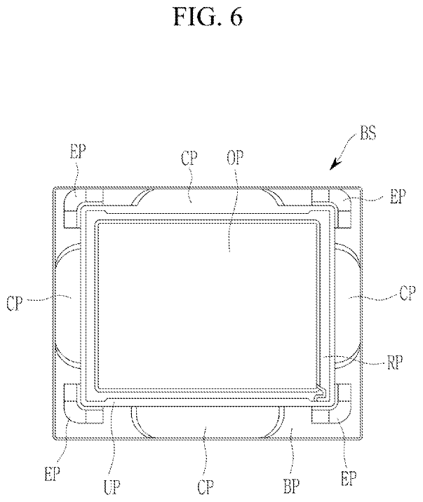

Hereinafter, a camera module according to another one or more embodiments will be described with reference to FIG. 6. FIG. 6 illustrates a top plan view of a portion of a camera module according to another one or more embodiments.

Referring to FIG. 6, similarly to the embodiment described above with reference to FIG. 2 and FIG. 3, the sub-housing BS of the camera module may have a quadrangular planar shape; the sub-housing BS may include the bottom part BP that is disposed in an outer portion and has a relatively low thickness, the protrusion UP that protrudes from the bottom BP and surrounds the opening OP, and the mounting part RP disposed between the protrusion UP and the opening OP and on which the filter part FT is mounted; and the protrusion UP may include the plurality of pattern parts CP disposed along the outer edge of the sub-housing BS and the outer edge of the mounting part RP.

The protrusion UP of the camera module, according to the present embodiment, may further include a plurality of corner pattern parts EP disposed between a point at which the outer edges of the sub-housing BS extending in different directions cross each other and a point at which the outer edges of the mounting part RP extending in different directions cross each other.

As described above, the plurality of pattern parts CP may have the highest height in a portion adjacent to the outer edge of the mounting part RP and may gradually decrease in height toward the four outermost edges of the sub-housing BS, and the upper surfaces of the plurality of pattern parts CP may have a convexly curved shape in a direction from the central portion of the image sensor IS toward the housing CS. Similarly, the height of the plurality of corner pattern parts EP may be the highest in a portion adjacent to the mounting part RP and may gradually decrease in height as it is adjacent to the sub-housing BS, and the upper surface of the plurality of corner pattern parts EP may have a convexly curved shape in a direction from the central portion of the image sensor IS toward the housing CS.

Accordingly, the light incident toward the sub-housing BS may be reflected in various directions along the direction from the convexly curved surfaces of the plurality of pattern parts CP and the plurality of corner pattern parts EP toward the outer portion of the sub-housing BS. Accordingly, without including an additional structure between the lens barrel LZ and the image sensor IS, the flare phenomenon may be prevented by reducing the light that may be reflected from the sub-housing BS and incident toward the lens barrel LZ.

Most features of the camera module, according to the embodiment described above with reference to FIG. 1 to FIG. 4, are substantially applicable to the camera module according to the present embodiment.

Embodiments described disclose a camera module that may prevent a flare phenomenon that may occur when light passing through a lens is re-incident on a surface of the lens and then is diffusely reflected on the surface of the lens.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A camera module comprising:
a lens barrel;
a housing configured to accommodate the lens barrel;
an image sensor disposed below the lens barrel and mounted on a substrate, along an optical axis direction of the lens barrel; and
a sub-housing, disposed between the lens barrel and the substrate, comprising an opening in which the image sensor is accommodated and a protrusion having a convexly curved upper surface shape configured to extend toward the lens barrel.

2. The camera module of claim 1, wherein
the sub-housing further includes a bottom part disposed at an outer portion of the opening to surround the opening, and
the protrusion convexly protrudes along a direction extending from a central portion of the image sensor toward the housing.

3. The camera module of claim 2, wherein
the sub-housing further includes a mounting part disposed between the protrusion and the opening, and
the camera module further includes a filter part accommodated in the mounting part.

4. The camera module of claim 3, wherein
a thickness of the mounting part is greater than a thickness of the bottom part, and is smaller than a thickness of the protrusion.

5. The camera module of claim 4, wherein
the sub-housing has a quadrangular planar shape.

6. The camera module of claim 5, wherein
the opening has a quadrangular planar shape.

7. The camera module of claim 6, wherein
the mounting part has a quadrangular planar shape.

8. The camera module of claim 7, wherein
the protrusion includes a plurality of pattern parts disposed along an edge of the mounting part and an outermost edge of the sub-housing, respectively, and having the convexly curved upper surface shape.

9. The camera module of claim 8, wherein
the protrusion further includes a plurality of corner pattern parts disposed between a plurality of first points at which outer edges of the sub-housing, extending in different directions, cross each other and a plurality of second points at which outer edges of the mounting part, extending in different directions, cross each other.

10. The camera module of claim 9, wherein
upper surfaces of the plurality of corner pattern parts have convexly curved shape shapes.

11. The camera module of claim 10, wherein
the plurality of corner pattern parts have a shape of the surface convexly protruding along a direction extending from a central portion of the image sensor toward the housing.

12. The camera module of claim 1, wherein
the sub-housing further includes a mounting part disposed between the protrusion and the opening, and
the camera module further includes a filter part accommodated in the mounting part.

13. The camera module of claim 12, wherein
each of the sub-housing, the opening, and the mounting part has a quadrangular planar shape.

14. The camera module of claim 13, wherein
the protrusion includes a plurality of pattern parts disposed along an edge of the mounting part and an outermost edge of the sub-housing, respectively, and having the convexly curved upper surface shape.

15. The camera module of claim 14, wherein
the protrusion further includes a plurality of corner pattern parts disposed between a plurality of first points at which outer edges of the sub-housing, extending in different directions, cross each other and a plurality of second points at which outer edges of the mounting part, extending in different directions, cross each other.

16. The camera module of claim 15, wherein
upper surfaces of the plurality of corner pattern parts have convexly curved shapes.

17. The camera module of claim 16, wherein
the corner pattern part has a shape of the surface convexly protruding along a direction extending from a central portion of the image sensor toward the housing.

18. The camera module of claim 1, wherein
the protrusion includes a plurality of pattern parts respectively disposed along an outermost edge of the sub-housing and having the convexly curved upper surface shape, and
a plurality of corner pattern parts, disposed at a plurality of first points at which outer edges of the sub-housing extending in different directions, cross each other.

19. The camera module of claim 18, wherein
upper surfaces of the plurality of corner pattern parts have convexly curved shapes.

20. The camera module of claim 19, wherein
the corner pattern part has a shape of the surface convexly protruding along a direction extending from a central portion of the image sensor toward the housing.
